(19) United States
(12) Patent Application Publication
(10) Pub. No.: US 2026/0173581 A1
(43) Pub. Date: Jun. 18, 2026

(54) PROCESS FOR MANUFACTURING A LIGHT-EMITTING DIODE

(71) Applicant: COMMISSARIAT À L'ENERGIE ATOMIQUE ET AUX ENERGIES ALTERNATIVES, PARIS (FR)

(72) Inventors: Florian DUPONT, GRENOBLE (FR); Kevin GUY, Grenoble (FR)

(21) Appl. No.: 19/392,660

(22) Filed: Nov. 18, 2025

(30) Foreign Application Priority Data
Dec. 12, 2024 (FR) 2414026

(51) Int. Cl. H10H 20/01

(52) U.S. Cl. CPC H10H 20/01335; H10H 20/032

(57) ABSTRACT

A process for manufacturing a light-emitting diode, includes providing a sapphire substrate; depositing, on the substrate, an epitaxial intermediate layer made of a transition metal nitride selected from: TiN, ZrN, HfN, NbN, TaN, VN, MoN, WN, CrN; depositing a buffer layer on the intermediate layer so as to obtain an epitaxial layer, the buffer layer being made of AlₓGa₁₋ₓN with 0≤x≤1; depositing, on the buffer layer, a light-emitting-diode stack including an active layer, and an injection layer on either side of the active layer; bonding a transfer substrate to the stack by virtue of a bonding layer; and carrying out laser lift-off of the substrate by applying a laser beam through the substrate and the intermediate layer, the laser beam having an emission wavelength that is absorbed by the intermediate layer.

### CROSS-REFERENCE TO RELATED APPLICATION

This application claims priority to foreign French patent application No. FR 2414026, filed on Dec. 12, 2024, the disclosure of which is incorporated by reference in its entirety.

### FIELD OF THE INVENTION

The invention relates to a process for manufacturing a light-emitting diode, and in particular to a process for manufacturing a light-emitting diode using laser lift-off of a sapphire substrate.

### BACKGROUND

Manufacturing light-emitting diodes (LEDs) on a sapphire substrate has many advantages such as, for example, compatibility in terms of lattice parameter with an active material AlGaN used in LEDs emitting in the UV range and limitation of manufacturing defects in the various layers of the LEDs.

However, sapphire is a material that has a refractive index much higher than the refractive index of air. This difference in refractive index results in a low critical angle at an air-sapphire interface, the critical angle being the maximum angle of incidence at which a photon is able to escape from the LED. The photons emitted by the active layer in the LED thus experience substantial internal reflection. The photons are therefore unable to escape from the LED and are thus lost as regards emission into air. Thus, prior-art LEDs comprising a sapphire substrate have a low light extraction efficiency (LEE).

One way of increasing the light extraction efficiency of LEDs on sapphire substrates is to roughen (increase the roughness of) the side of the sapphire substrate making contact with air. This makes it possible to modify the angle of incidence of the photons and therefore the critical angle. However, sapphire is a hard material and is therefore difficult and expensive to roughen.

Another solution is to use AlN substrates, which compared to sapphire have a refractive index closer to the refractive index of air. However, existing AlN substrates are too thin and/or too expensive for commercial applications.

Another solution is to remove the sapphire substrate once the LED has been manufactured, by laser lift-off. This process is already used for blue LEDs and LEDs emitting in the UV-A range (between 315 and 400 nm), a GaN buffer layer deposited between the sapphire substrate and the other functional layers of the diode being employed in these cases. The GaN buffer layer allows the emitted laser beam to be strongly absorbed with a view to achieving lift-off, and thus allows the sapphire substrate to be debonded (see, for example, Kawan, A. et al. Trans. Elec. Mat. 2021 (22), 128-132). However, it is not possible to use the GaN buffer layer at wavelengths in the UV-C (between 100 nm and 280 nm) because GaN absorbs wavelengths in the UV-C and therefore the wavelengths emitted by the LED itself. In addition, in the UV-A, a GaN buffer layer having a large thickness is necessary in order to achieve laser lift-off, resulting in a long deposition time. Furthermore, the difference in lattice parameter between GaN and the active material AlGaN used in UV-emitting LEDs leads to substantial defects in the layers deposited on the buffer layer.

An AlN buffer layer would make it possible to decrease defects in the layers deposited above the buffer layer, given the lattice parameters of AlN, which are closer to those of AlGaN. Results have been demonstrated that, with AlN buffer layers, fewer manufacturing defects would be generated. However, in the prior art, laser lift-off of sapphire substrates with an AlN buffer layer requires an energy density about four times higher than the energy density used with a GaN buffer layer (see for example Aoshima, H. et al. Phys. Status. Solidi 2012, 753-756). In addition, the high energy density of the laser deteriorates the other layers of the LED.

### SUMMARY OF THE INVENTION

In order to overcome the aforementioned drawbacks of laser sources, the invention provides a process for manufacturing a light-emitting diode, the process comprising the following steps:
a—providing a sapphire substrate;
b—depositing a layer, called the intermediate layer, on the substrate so as to obtain an epitaxial intermediate layer, the intermediate layer being made of a transition metal nitride selected from: TiN, ZrN, HfN, NbN, TaN, VN, MoN, WN, CrN;
c—depositing a layer, called the buffer layer, on the intermediate layer so as to obtain an epitaxial layer, the buffer layer being made of AlxGa1-xN with 0<x<1;
d—depositing, on the buffer layer, a stack performing a light-emitting-diode function, the stack comprising at least one active layer, and an injection layer on either side of the active layer;
e—bonding a substrate, called the transfer substrate, to the stack by virtue of at least one bonding layer; and
f—carrying out laser lift-off of the sapphire substrate by applying a laser beam at least through the sapphire substrate and the intermediate layer, the laser beam having an emission wavelength configured to be absorbed by the intermediate layer.

In one embodiment, the process further comprises the following step, performed after step d): d′—annealing the substrate, the buffer layer and the intermediate layer at a temperature above 1500° C.

In one embodiment, the buffer layer has a first side making contact with the stack and a second side opposite the first side, the process further comprising the following step, performed after step f):
g—roughening the second side of the buffer layer.

In one embodiment, the intermediate layer has a thickness between 5 and 50 nm.

In one embodiment, bonding step e) is carried out with a bonding layer placed on the transfer substrate or on the stack.

In one embodiment, bonding step e) is carried out with a first bonding layer and a second bonding layer, bonding step e) comprising the substeps:
e1—depositing the first bonding layer on the transfer substrate;
e2—depositing the second bonding layer on the stack;
e3—bringing the first bonding layer and the second bonding layer into contact; and
e4—heating the first bonding layer and the second bonding layer so as to bond them.

In one embodiment, step c) of depositing the buffer layer on the intermediate layer is carried out by physical vapor deposition (PVD) or by metal-organic chemical vapor deposition (MOCVD).

In one embodiment, step d) of depositing the stack is carried out by metal-organic chemical vapor deposition (MOCVD).

In one embodiment, a material of the intermediate layer deposited in step b) is configured to absorb ultraviolet light, and wherein the laser beam used in step f) is configured to emit ultraviolet light.

In one embodiment, the laser beam has an emission wavelength of 265 nm.

In one embodiment, the intermediate layer is made of TiN and the buffer layer is made of AlN.

In one embodiment, one of the at least one bonding layer comprises titanium and/or copper.

In one embodiment, step d) of depositing said stack performing a light-emitting-diode function is configured to produce a light-emitting diode emitting in a range 200-280 nm.

In one embodiment, the intermediate layer is made of a transition metal nitride selected from: TiN, ZrN, HfN, NbN, TaN, VN.

The following description presents a number of examples of embodiment of the device of the invention: these examples do not limit the scope of the invention. These examples of embodiment not only have features essential to the invention but also additional features associated with the embodiments in question.

### BRIEF DESCRIPTION OF THE DRAWINGS

The invention will be better understood and other advantages will become apparent on reading the following non-limiting description with reference to the figures, in which:

FIG. 1 illustrates a process for manufacturing an LED according to the invention.

### DETAILED DESCRIPTION

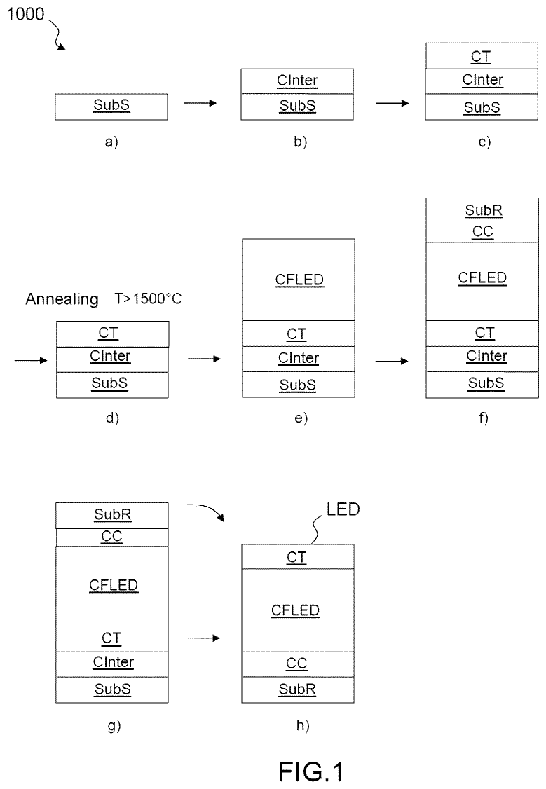

The invention relates to a process for manufacturing an LED. FIG. 1 illustrates a process 1000 for manufacturing a light-emitting diode LED according to the invention. The process comprises at least steps a) to f) described below.

In step a), the process 1000 consists in providing a sapphire substrate SubS.

In step b), the process 1000 consists in depositing a layer, called the intermediate layer Clnter, on the substrate SubS so as to obtain an epitaxial intermediate layer Clnter, the intermediate layer being made of a nitride of transition metals selected from: TiN, ZrN, HfN, NbN, TaN, VN.

In step c), the process 1000 consists in depositing a layer, called the buffer layer CT, on the intermediate layer Clnter so as to obtain an epitaxial layer, the buffer layer CT being made of AlxGa1-xN with 0<x<1.

In step d), the process consists in depositing, on the buffer layer, a stack CFLED performing a light-emitting-diode function, the stack comprising at least one active layer (CA), and an injection layer (CI1, CI2) on either side of the active layer.

The stack CFLED comprises a first injection layer CI1 doped p-type and a second injection layer CL2 doped n-type.

The buffer layer CT is placed between the stack CFLED and the sapphire substrate SubS. The buffer layer CT allows the transition to be made between the sapphire substrate SubS and the stack CFLED in terms of lattice parameter. Specifically, the difference in lattice parameter between sapphire and the active material of the LED included in the stack CFLED is large, and the buffer layer CT thus makes it possible to limit the defects that would otherwise be generated by this difference in lattice parameter.

In step e), the process 1000 consists in bonding a substrate, called the transfer substrate SubR, to the stack by virtue of at least one bonding layer (CC).

In step f), the process 1000 consists in carrying out laser lift-off of the sapphire substrate SubS by applying a laser beam RL at least through the sapphire substrate SubS and the intermediate layer Cinter, the laser beam RL having an emission wavelength configured to be absorbed by the intermediate layer Cinter. The intermediate layer Cinter therefore makes it possible, via its absorption of the laser beam RL, to implement the laser lift-off.

The process according to the invention makes it possible to benefit from the advantages of a sapphire substrate during the growth and production of the stack CFLED, and the subsequent lift-off of this substrate makes it possible to produce laser diodes that emit at a length that would have been absorbed by the sapphire substrate. The lift-off also allows the buffer layer CT to be roughened, in order to limit internal reflection of photons.

Advantageously, the invention uses an intermediate layer CInter the material of which absorbs in the UV, thus making it possible, in combination with a laser beam RL also emitting in the UV, to lift off the sapphire substrate SubS with a low energy density and thereby limit degradation of the other layers of the light-emitting diode. In addition, an intermediate layer Cinter made of materials selected from: TiN, ZrN, HfN, NbN, TaN, VN, MoN, WN, CrN makes it possible to grow by epitaxy the various layers deposited on the intermediate layer. These materials absorb in the UV-C. The material of the intermediate layer is preferably selected from TiN, ZrN, HfN, NbN, TaN, VN which are easier to implement.

In one embodiment, also illustrated in FIG. 1, the process comprises a step d′) after step d). In step d′), the process 1000 consists in annealing the substrate SubS, the buffer layer CT and the intermediate layer CInter at a temperature above 1500° C. This anneal makes it possible to crystallize the buffer layer CT and the intermediate layer Cinter allowing a stack CFLED of good quality, i.e. with a limited number of defects, to be grown.

In one embodiment, a material of the intermediate layer deposited in step b) is configured to absorb ultraviolet light, and wherein the laser beam RL used in step f) is configured to emit ultraviolet light.

In one embodiment, step d) of depositing the stack CFLED performing an LED function is configured to produce a light-emitting diode LED emitting in a range 200-280 nm.

In one embodiment, the stack CFLED comprises at least one contact layer, at least one contact layer of which is made of metal. For example, at least one contact layer is deposited between the upper injection layer and the bonding layer. By “upper injection layer” what is meant is the injection layer placed on the side opposite the sapphire substrate with respect to the active layer. According to one embodiment, a contact layer is deposited on either side of the stack.

In one embodiment, the process 1000 further comprises depositing one or more transition layers allowing defects to be limited. For example, a transition layer is deposited, after step c), on the buffer layer CT. The buffer layer CT and the transition layer thus allow a lattice transition between the sapphire and the layers of the stack CFLED.

For example, the buffer layer CT is made of AlN and the active layer is made of GaN. In this case, the transition layer is made of AlGaN, thus allowing a transition between the buffer layer CT and the layers of the LED stack in terms of lattice parameters, this limiting defects.

In one embodiment, the active layer of the stack CFLED is made up of quantum wells, for example AlGaN quantum wells.

The buffer layer CT has a first side making contact with the stack CFLED and a second side opposite the first side. According to one embodiment, the process further comprises a step g) that consists in roughening (increasing the roughness of) the second side of the buffer layer, step h) being performed after step f). Making the buffer layer CT rough limits internal reflections and allows the light extraction efficiency of the LED to be increased, i.e. the number of photons output by the diode to be increased.

In one embodiment, the intermediate layer Cinter has a thickness between 5 and 50 nm. Advantageously, this thickness enables a high absorption of the laser beam RL having a wavelength in the UV, thus making it possible to perform a lift-off with a low laser energy density, and thereby limit the defects generated in underlying layers by the lift-off.

In one embodiment, bonding step e) is carried out with the bonding layer CC placed on the transfer substrate SubR or on the stack CFLED.

In a first example, the bonding layer CC is placed solely on the transfer substrate SubR. In this case, bonding step e) comprises the following substeps: a step e1″) consisting in depositing the bonding layer on the transfer substrate SubR, a step e2′) consisting in bringing the bonding layer and the stack CFLED into contact, and a step e3′) consisting in heating the bonding layer so as to bond the stack CFLED and the transfer substrate SubR.

In a second example, the bonding layer CC is placed solely on the stack CFLED. In this case, bonding step e) comprises the following substeps: a step e1″) consisting in depositing the bonding layer on the stack CFLED, a step e2″) consisting in bringing the bonding layer and the transfer substrate SubR into contact, and a step e3″) consisting in heating the bonding layer so as to bond the stack CFLED and the transfer substrate SubR.

In another embodiment, bonding step e) is carried out with a first bonding layer and a second bonding layer, bonding step e) comprising the following substeps: a step e1) consisting in depositing the first bonding layer on the transfer substrate SubR, a step e2) consisting in depositing the second bonding layer on the stack CFLED, a step e3) consisting in bringing the first bonding layer and the second bonding layer into contact, and a step e4) consisting in heating the first bonding layer and the second bonding layer so as to bond them. Thus, in this example, two bonding layers CC are respectively placed on the transfer substrate SubR and on the stack CFLED, which are then brought into contact in order to bond the transfer substrate SubR to the stack CFLED.

For example, the heating step is performed at 110° C.

In one embodiment, one of the at least one bonding layer comprises titanium and/or copper.

In one embodiment, step c) of depositing the buffer layer CT on the intermediate layer Clnter is carried out by physical vapor deposition (PVD), for example using a technique such as reactive sputtering or pulsed laser deposition (PLD), or by metal-organic chemical vapor deposition (MOCVD). Advantageously, metal-organic chemical vapor deposition (MOCVD) makes it possible to limit defects in the buffer layer CT.

In one embodiment, step d) of depositing the stack CFLED is carried out by metal-organic chemical vapor deposition (MOCVD). Advantageously, this makes it possible to limit defects in the stack CFLED.

In one embodiment, the laser beam RL has an emission wavelength of 265 nm. Advantageously, this makes it possible to use a low energy density to carry out the laser lift-off, avoiding degradation in the lift-off step.

In one embodiment, the intermediate layer is made of TiN and the buffer layer is made of AlN.

To highlight the effects of the intermediate layer in the present invention, the inventors performed tests on two LEDs obtained using the process 1000 described above, having an intermediate layer of TiN of 5 nm and 20 nm thickness respectively, and on one LED obtained using a manufacturing process without the step of depositing the intermediate layer Cinter. These three examples of LEDs possessed a 400 nm AlN buffer layer CT.

A first X-ray diffraction test was carried out on the three LEDs. An omega-scan (rocking curves) was carried out on the three LEDs. The diffraction peaks obtained by X-ray diffraction for two crystal planes were measured and their full width at half maximum determined. Table 1 below discloses the results of the full widths at half maximum determined for the peaks.

The results clearly indicate that the full widths at half maximum of the peaks remains approximately constant and therefore that the intermediate layer Cinter does not degrade the crystallinity of the layers of the LED.

A roughness second test was carried out on the three LEDs. The RMS roughness of the surface making contact with air of the buffer layer CT before step d), i.e. before growth of the stack CFLED, was measured. Table 1 above discloses the results of the measured RMS roughness.

The results clearly indicate that RMS roughness decreases when the intermediate layer Cinter is used in the manufacture of the LED. This means that the roughness of the surface of the buffer layer CT making contact with air decreases when the intermediate layer Cinter is used during manufacture. It is necessary to have a minimum roughness to grow a stack CFLED with a minimum of defects.

Thus, the intermediate layer Cinter makes it possible to preserve the crystallinity of the layers while decreasing roughness.

TABLE 1
the full width at half maximum of the diffraction peaks obtained
by X-ray diffraction for various crystal planes and the RMS
roughness of the surface of the buffer layer of various examples
of LEDs obtained with or without an intermediate TiN layer.

| | | TiN 5 nm + | TiN 20 nm + |
|---|---|---|---|
| | AlN 400 nm | AlN 400 nm | AlN 400 nm |
| XRD peak width | 0.21° | 0.23° | 0.25° |
| Crystal plane (002) | | | |
| XRD peak width | 0.38° | 0.30° | 0.36° |
| Crystal plane (102) | | | |
| RMS roughness | 1.04 nm | 0.77 nm | 0.80 nm |

It will be noted that, in the preceding description, the term “epitaxy” is understood to mean an ordered growth process.

Although the invention has been illustrated and described in detail using one preferred embodiment, the invention is not limited to the disclosed examples. Other variants will be able to be inferred by anyone skilled in the art without departing from the scope of protection of the claimed invention.

1. A process for manufacturing a light-emitting diode (LED), the process comprising the following steps:
a—providing a sapphire substrate (SubS);
b—depositing a layer, called the intermediate layer (Cinter), on the substrate so as to obtain an epitaxial intermediate layer, the intermediate layer being made of a transition metal nitride selected from: TiN, ZrN, HfN, NbN, TaN, VN, MoN, WN, CrN;
c—depositing a layer, called the buffer layer (CT), on the intermediate layer so as to obtain an epitaxial layer, the buffer layer being made of AlₓGa₁₋ₓN with 0≤x≤1;
d—depositing, on the buffer layer, a stack (CFLED) performing a light-emitting-diode function, the stack comprising at least one active layer (CA), and an injection layer (CI1, CI2) on either side of the active layer;
e—bonding a substrate, called the transfer substrate (SubR), to the stack by virtue of at least one bonding layer (CC); and
f—carrying out laser lift-off of the sapphire substrate by applying a laser beam at least through the sapphire substrate and the intermediate layer, the laser beam (RL) having an emission wavelength configured to be absorbed by the intermediate layer.

2. The process as claimed in claim 1, the process further comprising the following step, performed after step d):
d′—annealing the substrate, the buffer layer and the intermediate layer at a temperature above 1500° C.

3. The process as claimed in claim 1, the buffer layer having a first side making contact with the stack and a second side opposite the first side, the process further comprising the following step, performed after step f):
g—roughening the second side of the buffer layer.

4. The process as claimed in claim 1, wherein the intermediate layer (Cinter) has a thickness between 5 and 50 nm.

5. The process as claimed in claim 1, wherein bonding step e) is carried out with a bonding layer placed on the transfer substrate or on the stack.

6. The process as claimed in claim 1, wherein bonding step e) is carried out with a first bonding layer and a second bonding layer, bonding step e) comprising the substeps:
e1—depositing the first bonding layer on the transfer substrate;
e2—depositing the second bonding layer on the stack;
e3—bringing the first bonding layer and the second bonding layer into contact; and
e4—heating the first bonding layer and the second bonding layer so as to bond them.

7. The process as claimed in claim 1, wherein step c) of depositing the buffer layer on the intermediate layer is carried out by physical vapor deposition (PVD) or metal-organic chemical vapor deposition (MOCVD).

8. The process as claimed in claim 1, wherein step d) of depositing the stack is carried out by metal-organic chemical vapor deposition (MOCVD).

9. The process as claimed in claim 1, wherein a material of the intermediate layer deposited in step b) is configured to absorb ultraviolet light, and wherein the laser beam (RL) used in step f) is configured to emit ultraviolet light.

10. The process as claimed in claim 9, wherein the laser beam has an emission wavelength of 265 nm.

11. The process as claimed in claim 1, wherein the intermediate layer is made of TiN and the buffer layer is made of AlN.

12. The process as claimed in claim 1, wherein one of the at least one bonding layer comprises titanium and/or copper.

13. The process as claimed in claim 1, wherein step d) of depositing said stack performing a light-emitting-diode function is configured to produce a light-emitting diode emitting in a range 200-280 nm.

14. The process as claimed in claim 1, wherein the intermediate layer is made of a transition metal nitride selected from: TiN, ZrN, HfN, NbN, TaN, VN.
